(19) United States
(12) Patent Application Publication
(10) Pub. No.: US 2014/0054742 A1
(43) Pub. Date: Feb. 27, 2014

(54) Semiconductor Structure

(71) Applicant: Agency for Science, Technology and Research, Singapore (SG)

(72) Inventor: Guruprasad Katti, Singapore (SG)

(73) Assignee: Agency for Science, Technology and Research, Singapore (SG)

(21) Appl. No.: 14/011,036

(22) Filed: Aug. 27, 2013

(30) Foreign Application Priority Data
Aug. 27, 2012 (SG) SG201206356-6
Dec. 6, 2012 (SG) SG201208983-5

(51) Int. Cl. H01L 23/522

(52) U.S. Cl. CPC H01L 23/5223
USPC 257/503

(57) ABSTRACT

Various embodiments provide a semiconductor structure. The semiconductor structure may include a semiconductor substrate; a via extending through the semiconductor substrate; and a capacitive structure surrounding at least a portion of the via. The capacitive structure may include a metal layer formed on the semiconductor substrate.

### CROSS-REFERENCE TO RELATED APPLICATIONS

The present application claims the benefit of priority of Singapore patent application 201206356-6 filed on Aug. 27, 2012 and Singapore patent application 201208983-5 filed on Dec. 6, 2012, the entire contents of which are incorporated herein by reference for all purposes.

### TECHNICAL FIELD

Embodiments relate generally to a semiconductor structure, and particularly relate to a semiconductor structure having a via.

### BACKGROUND

Amongst numerous upcoming semiconductor technologies, 2.5 Dimensional (2.5D) Through Silicon Interposer (TSI) as well as Three Dimensional (3D) Integrated Circuit (IC) technologies are demonstrating significant promise towards building cutting edge high speed VLSI (Very-large-scale integration) circuits and systems. Through Silicon Via (TSV) interconnects running vertically through silicon are instrumental in establishing electrical connections between inter-die nodes.

Three dimensional integrated circuits provide many advantages. For example, 3D ICs could alleviate some CMOS scaling related performance limitations (e.g. interconnect bottleneck), reduce system size, allow heterogeneous integration (e.g. Memory-Logic integration, III-V to Si integration, etc.), and enable novel systems using high density TSV approach.

FIG. 1 illustrates a diagram of a 3D integrated circuit 100, in which a plurality of components, circuits, dies and/or interposer may be stacked and integrated, such as sensor, RF (radio frequency), FPGA (field-programmable gate array), memory, board/Interposer, probes and battery being stacked vertically. The vertical connections among the stacked layers may be achieved through TSVs.

FIG. 2 shows an exemplary TSV structure 200 in a cross-sectional side view and a cross-sectional top view, along with a lumped RC model of the TSV.

As shown in FIG. 2, the TSV 220 enable the interconnection between a top die and a bottom die, wherein the top die and the bottom die are bonded through a BCB (Benzocyclobutene) bonding layer 202. At the side of the top die, the TSV 220 extends through a substrate 204 and a pre-metal dielectric (PMD) layer 206 and receives TSV Bias voltage through a contact pad formed on the PMD layer 206. At the side of the bottom die, a landing pad formed in an inter-metal dielectric (IMD) layer 208 connects the body of the TSV 220, and the IMD layer 208 is further connected to a copper layer 210. The copper layer 210 may have a resistivity ρ of about 1.68 e-8 Ω·, for example.

The TSV 220 includes a conductive fill 222 surrounded by a dielectric layer 224. The dimension of the TSV 220 may include a TSV length L_{TSV}, a TSV dielectric thickness tₒₓ, and a TSV diameter φ_{TSV}. The PMD layer 206 may have a predetermined thickness and permittivity.

FIG. 2 further shows a cross-sectional top view 230 of the TSV formed in the substrate 204, wherein the substrate 204 is grounded. The substrate 204 may be a p-Si substrate, for example. The TSV includes the conductive fill 222 surrounded by an oxide dielectric layer 224. In operation, a depletion region 226 may be formed outside the oxide dielectric layer 224, which may introduce a TSV depletion capacitance C_{dep}.

A corresponding TSV lumped RC model 240 of the TSV 220 is illustrated by G. Katti et al. in “3D stacked ICs using Cu TSVs and die to wafer hybrid collective bonding, IEDM 2009, pp. 357-360”. In the lumped RC model 240, the equivalent circuit of the TSV 220 includes TSV resistance R_{TSV}, TSV oxide capacitance Cₒₓ and TSV depletion capacitance C_{dep}.

The parasitic resistance (R_{TSV}), capacitance (C_{TSV}) and inductance (L_{TSV}) of TSV architectures have also been modeled and characterized, e.g., by G. Katti et al. in “Electrical modeling & characterization of through silicon via (TSV) for 3D ICs, IEEE Trans. Electron Devices, vol. 57, no. 1, pp. 256-262, January 2010”, to establish their impact on 3D circuits and systems. It has been shown that R_{TSV} has minimal impact on the delay of 3D circuits, whereas C_{TSV} is the most dominant parasitic component impacting the electrical performance of 3D circuits and systems. In order to build high speed VLSI systems, existing highly capacitive TSVs become a major bottleneck and the TSV capacitance should be reduced.

Various methods to reduce the C_{TSV} by operating the TSV in the depletion region have been proposed. However, the TSV capacitance C_{TSV} of the contemporary TSV architectures for 2.5D TSI technologies (e.g. the dimensions of the TSV are φ_{TSV}=12 μm, L_{TSV}=100 μm, and a doping concentration of Na=1.4×10¹⁵/cm³) and 3D ICs (e.g.

the dimensions of the TSV are φ_{TSV}=5 μm, L_{TSV}=50 μm, and a doping concentration of Na=1.4×10¹⁴/cm³) is estimated to be 100 fF and 50 fF respectively, which is still much larger compared to the capacitance contribution of about 0.02 fF/μm for the Back End of Line (BEOL) interconnects.

In TSV architectures with p+ substrate contact, the lower TSV depletion capacitance may be achieved by employing larger fixed oxide charges and low density of interface states at the Si—SiO₂ interface. In TSV architectures with ohmic p+ substrate contact, the TSV oxide capacitance (Cₒₓ) is lowered due to the combination of depletion capacitance (C_{dep}) in series with the oxide capacitance. The effective TSV capacitance C_{TSV} is given as 1/C_{TSV}=1/Cₒₓ+1/C_{dep}, and is close to the smaller value of Cₒₓ and C_{dep} in series.

It is required to further reduce the TSV capacitance C_{TSV} to meet the increasingly steep speed and power requirements in 3D circuits and systems.

### SUMMARY

Various embodiments provide a semiconductor structure. The semiconductor structure may include a semiconductor substrate; a via extending through the semiconductor substrate; and a capacitive structure surrounding at least a portion of the via. The capacitive structure may include a metal layer formed on the semiconductor substrate.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1 illustrates a diagram of a 3D integrated circuit.

FIG. 2 shows an exemplary TSV in a cross-sectional side view and a cross-sectional top view, along with a lumped RC model of the TSV.

FIG. 3 shows a semiconductor structure according to various embodiments.

FIG. 4 shows a top view of a semiconductor structure according to various embodiments.

FIG. 5 shows an electrical model of TSV in a semiconductor structure of FIGS. 3-4, according to various embodiments.

FIG. 6 shows a 3D view of a semiconductor structure according to various embodiments.

FIG. 7A shows simulated C-V characteristics for TSVs in 2.5D Through Silicon Interposer (TSI).

FIG. 7B shows simulated C-V characteristics for TSVs in 3D integrated circuits.

FIG. 8 shows simulated C-V characteristics for TSV of various embodiments in comparison to TSV with ohmic contact.

FIG. 9 shows a semiconductor structure according to various embodiments.

FIG. 10 shows a top view of a semiconductor structure according to various embodiments.

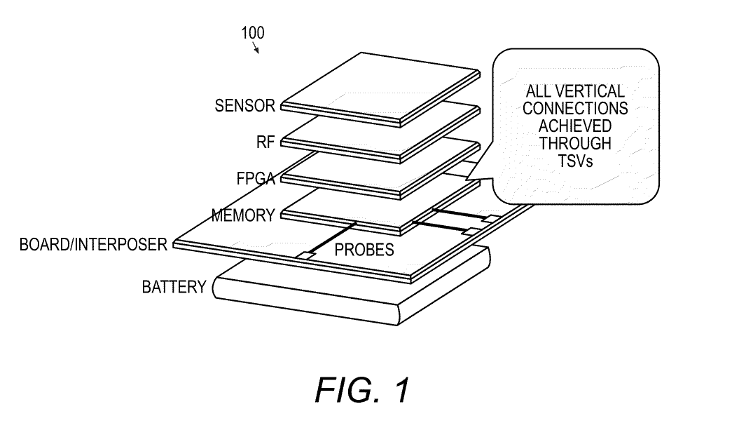

### DESCRIPTION

Various embodiments provide a semiconductor structure with reduced capacitance for a via.

In this context, a “circuit” may be understood as any kind of a logic implementing entity, which may be special purpose circuitry or a processor executing software stored in a memory, firmware, or any combination thereof. Thus, in an embodiment, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Any other kind of implementation of the respective functions which will be described in more detail below may also be understood as a “circuit” in accordance with an alternative embodiment.

Various embodiments provide a semiconductor structure. The semiconductor structure may include a semiconductor substrate; a via extending through the semiconductor substrate; and a capacitive structure surrounding at least a portion of the via. The capacitive structure may include a metal layer formed on the semiconductor substrate.

In this context, the capacitive structure may be a structure exhibiting a capacitance under working condition. The metal layer of the capacitive structure may be a metal pad formed on the semiconductor substrate, wherein the metal pad may be configured to receive a voltage. The capacitive structure may also be referred to as a capacitive contact, or a capacitive substrate contact.

In various embodiments, the capacitive structure may include or may be a Schottky contact formed by the metal layer and a region of the semiconductor substrate under the metal layer.

The semiconductor substrate may have a doping of a predetermined concentration and of a predetermined dopant type, and the region of the semiconductor substrate included in the Schottky contact may have a doping of the predetermined concentration and of the predetermined dopant type.

In various embodiments, the semiconductor substrate having the doping of the predetermined concentration may form an extrinsic semiconductor substrate. In various embodiments, the semiconductor substrate may be lightly doped, for example, with a doping concentration selected from a range from 10¹³/cm³ to 10¹⁶/cm³. The semiconductor substrate may be doped with p-type or n-type dopant. For example, the semiconductor substrate may be p-silicon or n-silicon substrate. The region of the semiconductor substrate forming the capacitive structure may be a p-doped region, e.g. may be a p-silicon region.

In various embodiments, the semiconductor substrate may be an intrinsic substrate, e.g., an un-doped substrate. The region of the semiconductor substrate included in the Schottky contact may have a doping of a predetermined concentration and of a predetermined dopant type. In various embodiments, the region of the semiconductor substrate included in the Schottky contact may be lightly doped, for example, with a doping concentration selected from a range from 10¹³/cm³ to 10¹⁶/cm³. The region of the semiconductor substrate included in the Schottky contact may be doped with p-type or n-type dopant. In various embodiments, the region of the semiconductor substrate included in the Schottky contact may be formed by doping a region of the semiconductor substrate under the top surface of the substrate on which the metal layer is to be deposited.

In various embodiments, the capacitive structure may include the metal layer and a p-n junction formed in the semiconductor substrate. The p-n junction may include a first region of the semiconductor substrate having the doping of a first concentration and of a first dopant type, and a second region of the semiconductor substrate have a doping of a second concentration and of a second dopant type, the second dopant type being opposite to the first dopant type. The second region of the semiconductor substrate is arranged in between the metal layer and the first region of the semiconductor substrate.

In various embodiments, the second concentration may be substantially similar to the first concentration. In various embodiments, the second concentration may be higher than the first concentration. In various embodiments, the second concentration may be at least one hundred times higher than the first concentration.

The first region of the semiconductor substrate may be a lightly doped region, e.g. having a doping concentration selected from a range from 10¹³/cm³ to 10¹⁶/cm³. The second region of the semiconductor substrate may be a heavily doped region, e.g. having a doping concentration selected from a range from 10¹⁸/cm³ to 10²²/cm³.

The first region and the second region may be respectively doped with opposite types of dopants selected from p-type and n-type dopants. For example, the first region may be a p-doped region of a p-type substrate, and the second region may be an n⁺-doped region formed in the p-type substrate. In another example, the first region may be an n-doped region of an n-type substrate, and the second region may be a p+-doped region formed in the n-type substrate.

The second region may be formed by doping a region of the semiconductor substrate next to the top surface of the substrate on which the metal layer is to be deposited, with a dopant type opposite to the dopant type of a lightly doped semiconductor substrate. The semiconductor substrate being lightly doped may be directly used for the first region of the p-n junction, without additional doping process.

The semiconductor substrate may be an intrinsic substrate, e.g., an un-doped substrate. The first region may be formed by doping a region of the semiconductor substrate under the top surface of the substrate on which the metal layer is to be deposited; and the second region may be formed by doping a region in between the first region and the top surface of the substrate.

The second region may be formed by depositing a doped region on the semiconductor substrate. The metal layer may be formed on top of the second region.

In various embodiments, the capacitive structure may include or may be a metal-oxide-semiconductor (MOS) contact. The capacitive structure may include the metal layer, a region of the semiconductor substrate under the metal layer, and an oxide layer arranged in between the metal layer and the region of the semiconductor substrate.

The oxide layer may be deposited on the surface of the semiconductor substrate, and the metal layer may be deposited on top of the oxide layer. The oxide layer may also be formed in a further region of the semiconductor substrate in between the metal layer and the region of the semiconductor substrate. For example, the oxide layer may be formed by oxidizing the further region of the semiconductor substrate next to the top surface of the substrate on which the metal layer is to be deposited. The oxide layer may be a silicon oxide (SiO₂) layer.

The semiconductor substrate and the region of the semiconductor substrate included in the MOS contact may be doped or un-doped. In various embodiments, the semiconductor substrate may be an intrinsic substrate, and the region of the semiconductor substrate included in the MOS contact may be un-doped. In various embodiments, the semiconductor substrate and the region of the semiconductor substrate included in the MOS contact may have a doping of a predetermined concentration and of a predetermined dopant type. The predetermined concentration may be a doping concentration selected from a range from 10¹³/cm³ to 10¹⁶/cm³.

In various embodiments, the via of the semiconductor structure may be formed within an opening through the semiconductor substrate. In this context, the via extending through the semiconductor substrate may be referred as a through silicon/substrate via (TSV). The via may include an insulating layer formed at a wall of the opening; and a conductive fill formed within the opening with the insulating layer surrounding the conductive fill. The insulating layer may be an oxide layer, e.g. a silicon oxide layer, or may be a nitride layer, e.g. a silicon nitride layer, or may be other types of insulating materials. The conductive fill may include a conductive material, such as metal or alloy (e.g. copper or tungsten or an alloy of copper or tungsten), or polysilicon.

In various embodiments, the metal layer of the capacitive structure may be formed at a distance away from the insulating layer of the via. Illustratively, a portion of the insulating layer of the via may be exposed at the top surface of the semiconductor substrate, and the metal layer may be formed at a distance away from the exposed insulating layer on the top surface of the semiconductor substrate.

In various embodiments, the metal layer of the capacitive structure may be formed as an annular layer surrounding the via on the surface of the semiconductor substrate and at a distance away from the via. The metal layer of the capacitive structure may also be formed in other shape or configuration, e.g. as a rectangle or square shaped layer surrounding the via on the surface of the semiconductor substrate and at a distance away from the via. In various embodiments, the metal layer of the capacitive structure may be formed at one or more locations on the top surface of the semiconductor substrate, the one or more locations may be at a distance away from the via, e.g. at a distance away from the portion of the via exposed on the top surface of the semiconductor substrate. In other words, one or more capacitive structures may be formed at a distance away from the via. In various embodiments, the metal layer of the capacitive structure may be formed such that it is spaced apart from the via.

The semiconductor structure as described in various embodiments above may be used or included in a 2.5D through silicon interposer, or in a 3D integrated circuit device.

Various embodiments further provide a through silicon interposer (TSI) having a semiconductor structure of various embodiments above.

2.5 dimensional (2.5D) integrated circuit is a form of 3D IC integration, and combines silicon interposer, microbump and TSV technologies to enable integration of heterogeneous, multi-die systems in a single package. The interposer or the through silicon interposer (TSI) may be utilized for interconnection in a 2.5D integrated circuit, and may be referred to as a 2.5D TSI.

Various embodiments further provide a three dimensional integrated circuit device having a semiconductor structure of various embodiments above. The three dimensional integrated circuit device may be referred to as a 3D IC device, using the semiconductor structure of various embodiments for vertical interconnections among vertically stacked dies/circuits/components.

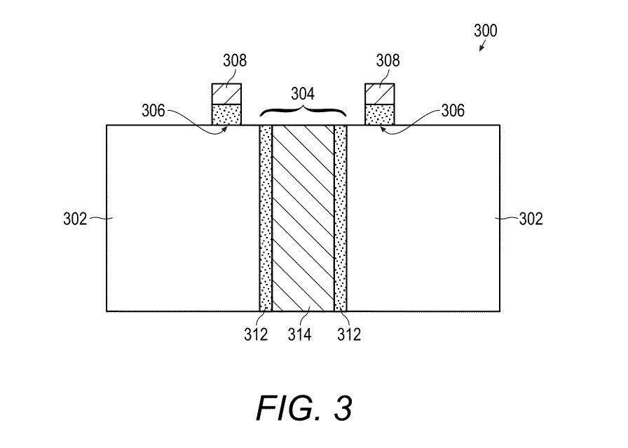

FIG. 3 shows a semiconductor structure 300 according to various embodiments.

In FIG. 3, a cross-sectional view of the semiconductor structure 300 is shown. The semiconductor structure 300 may include a semiconductor substrate 302; a via 304 extending through the semiconductor substrate 302; and a capacitive structure 306 surrounding at least a portion of the via 304. The capacitive structure 306 may include a metal layer 308 formed on the semiconductor substrate 302.

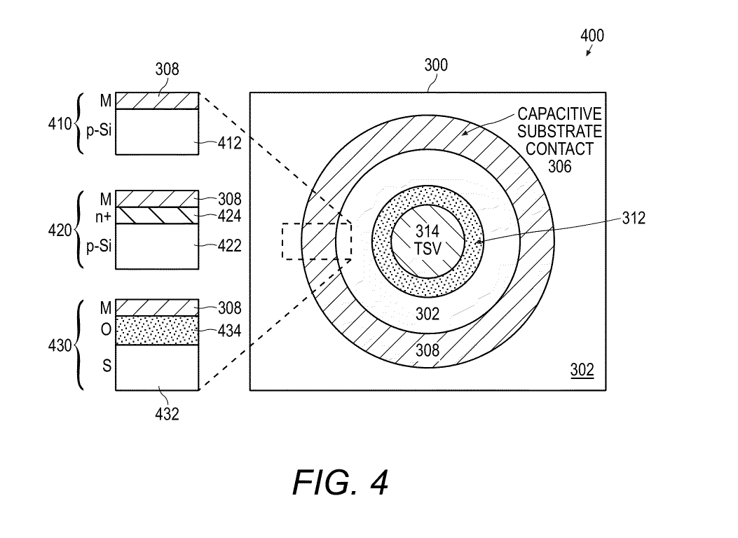

In the embodiments shown in FIG. 3, the capacitive structure 306 is shown to have two layers on the semiconductor substrate 302, which is to represent that the capacitive structure is a multiple-layer structure. However, in various embodiments as will be described in FIG. 4 below, only the metal layer of the capacitive structure 306 may be formed on the semiconductor substrate 302 while other portions of the capacitive structure 306 may be formed in the semiconductor substrate 302. The metal layer 308 of the capacitive structure 306 may be a metal pad formed on the semiconductor substrate 302, wherein the metal pad may be configured to receive a voltage.

In various embodiments, the via 304, also referred to as the TSV (through silicon/substrate via) 304, may be formed within an opening through the semiconductor substrate 302. The via may include an insulating layer 312 formed at a wall of the opening; and a conductive fill 314 formed within the opening with the insulating layer 312 surrounding the conductive fill 314. The insulating layer 312 may be an oxide layer, e.g. a silicon oxide (SiO₂) layer, or may be a nitride layer, e.g. a silicon nitride layer, or may be other types of insulating materials, e.g. a low-k material. The conductive fill 314 may include a conductive material, such as metal or alloy (e.g. copper or tungsten or an alloy of copper or tungsten), or polysilicon.

A top view 400 of the semiconductor structure 300 according to various embodiments is shown in FIG. 4.

As shown in the embodiments of FIG. 3 and FIG. 4, the metal layer 308 of the capacitive structure 300 may be formed at a distance away from the insulating layer 312 of the via 304. Illustratively, in the top view 400 of FIG. 4, a portion of the insulating layer 312 of the via 304 may be exposed at the top surface of the semiconductor substrate 302, and the metal layer 308 of the capacitive structure 306 may be formed at a distance away from the exposed insulating layer 312 on the top surface of the semiconductor substrate 302.

In various embodiments, the metal layer 308 of the capacitive structure 306 may be formed as an annular layer surrounding the via 304 on the surface of the semiconductor substrate 302 and at a distance away from the via 304. As shown in FIG. 4, the metal layer 308 is separated from the insulating layer 312 of the via 304 by the semiconductor substrate 302. In various embodiments, the metal layer 308 of the capacitive structure 306 may also be formed in other shape or configuration, e.g. as a rectangle or square shaped layer.

Although the embodiments of FIG. 4 shows a capacitive structure 306 formed as an annular structure surrounding the via, it is understood that one or more capacitive structures may be formed by forming one or more metal layers at one or more locations on the top surface of the semiconductor substrate 302, wherein the one or more capacitive structures may not be a continuous structure surrounding the via. The one or more locations may be at a distance away from the via, e.g. at a distance away from the insulating layer 312 of the via exposed on the top surface of the semiconductor substrate 302.

The capacitive structure 306 may have various configurations according to various embodiments. FIG. 4 shows three exemplary configurations 410, 420, 430 of the capacitive structure 306. It is understood that the capacitive structure 306 may have other configuration or layer arrangement in other embodiments, which exhibits a capacitance under working condition.

In various embodiments shown in 410, the capacitive structure 306 may include a Schottky contact 410 formed by the top metal layer 308 and a region 412 of the semiconductor substrate 302 under the metal layer 308.

The semiconductor substrate 302 may have a doping of a predetermined concentration and of a predetermined dopant type, and the region 412 of the semiconductor substrate included in the Schottky contact 410 may have a doping of the predetermined concentration and of the predetermined dopant type.

In various embodiments, the semiconductor substrate 302 having the doping of the predetermined concentration may form an extrinsic semiconductor substrate. In various embodiments, the semiconductor substrate 302 may be lightly doped, for example, with a doping concentration selected from a range from 10¹³/cm³ to 10¹⁶/cm³. The semiconductor substrate 302 may be doped with p-type or n-type dopant. For example, the semiconductor substrate may be p-silicon or n-silicon substrate. The region 412 of the semiconductor substrate forming the capacitive structure 410 may be a p-doped region, e.g., a region of the p-silicon substrate, and may be denoted by a p-Si region 412.

In various embodiments, the semiconductor substrate 302 may be an intrinsic substrate, e.g., an un-doped substrate. The region 412 of the semiconductor substrate included in the Schottky contact 410 may have a doping of a predetermined concentration and of a predetermined dopant type. In various embodiments, the region 412 of the semiconductor substrate included in the Schottky contact 410 may be lightly doped, for example, with a doping concentration selected from a range from 10¹³/cm³ to 10¹⁶/cm³. The region 412 of the semiconductor substrate included in the Schottky contact 410 may be doped with p-type or n-type dopant. In various embodiments, the region 412 of the semiconductor substrate included in the Schottky contact 410 may be formed by doping a region of the semiconductor substrate under the top surface of the substrate 302 on which the metal layer 308 is to be deposited.

In various embodiments shown in 420, the capacitive structure 306 may be a PN diode contact 420 including the metal layer 308 and a p-n junction formed in the semiconductor substrate 302. The p-n junction may include a first region 422 of the semiconductor substrate having the doping of a first concentration and of a first dopant type, and a second region 424 of the semiconductor substrate have a doping of a second concentration and of a second dopant type, the second dopant type being opposite to the first dopant type. The second region 424 of the semiconductor substrate is arranged in between the metal layer 308 and the first region 422 of the semiconductor substrate.

In various embodiments, the second concentration may be substantially similar to the first concentration. In various embodiments, the second concentration may be higher than the first concentration. In various embodiments, the second concentration may be at least one hundred times higher than the first concentration.

The first region 422 of the semiconductor substrate may be a lightly doped region, e.g. having a doping concentration selected from a range from 10¹³/cm³ to 10¹⁶/cm³. The second region 424 of the semiconductor substrate may be a heavily doped region, e.g. having a doping concentration selected from a range from 10¹⁸/cm³ to 10²²/cm³.

The first region 422 and the second region 424 may be respectively doped with opposite types of dopants selected from p-type and n-type dopants. For example, the first region 422 may be a p-doped region, e.g. a p-Si region of a p-type silicon substrate 302. The second region 424 may be an n⁺-doped region formed in the p-type silicon substrate 302. In another example not shown in FIG. 4, the first region 422 may be an n-doped region of an n-type substrate, and the second region 424 may be a p+-doped region formed in the n-type substrate.

The second region 424 may be formed by doping a region of the semiconductor substrate 302 next to the top surface of the substrate on which the metal layer 308 is to be deposited, with a dopant type opposite to the dopant type of the lightly doped semiconductor substrate. The semiconductor substrate 302 being lightly doped may be directly used for the first region 422 of the p-n junction, without additional doping process.

The semiconductor substrate 302 may be an intrinsic substrate, e.g., an un-doped substrate. The first region 422 may be formed by doping a region of the semiconductor substrate 302 under the top surface of the substrate 302 on which the metal layer 308 is to be deposited; and the second region 424 may be formed by doping a region on top of the first region 422, i.e. the region in between the first region 422 and the top surface of the substrate 302.

In various embodiments, the second region 424 may also be formed by depositing a doped region on the semiconductor substrate 302. The metal layer 308 may be formed on top of the second region 424.

In various embodiments shown in 430, the capacitive structure 306 may include a metal-oxide-semiconductor (MOS) contact 430. The MOS contact 430 may include the metal layer 308, a region 432 of the semiconductor substrate 302 under the metal layer 308, and an oxide layer 434 arranged in between the metal layer 308 and the region 432 of the semiconductor substrate.

The oxide layer 434 may be deposited on the surface of the semiconductor substrate 302, and the metal layer 308 may be deposited on top of the oxide layer 434. The oxide layer 434 may also be formed in the semiconductor substrate 302, e.g., in a further region 434 of the semiconductor substrate 302 in between the metal layer 308 and the region 432 of the semiconductor substrate. For example, the oxide layer 434 may be formed by oxidizing the further region 434 of the semiconductor substrate next to the top surface of the substrate on which the metal layer 308 is to be deposited. The oxide layer 434 may be a silicon oxide (SiO₂) layer.

The semiconductor substrate 302 and the region 432 of the semiconductor substrate included in the MOS contact 430 may be doped or un-doped. In various embodiments, the semiconductor substrate 302 may be an intrinsic substrate, and the region 432 of the semiconductor substrate included in the MOS contact 430 is un-doped. In various embodiments, the semiconductor substrate 302 and the region 432 of the semiconductor substrate included in the MOS contact 430 may have a doping of a predetermined concentration and of a predetermined dopant type. The predetermined concentration may be a doping concentration selected from a range from 10¹³/cm³ to 10¹⁶/cm³.

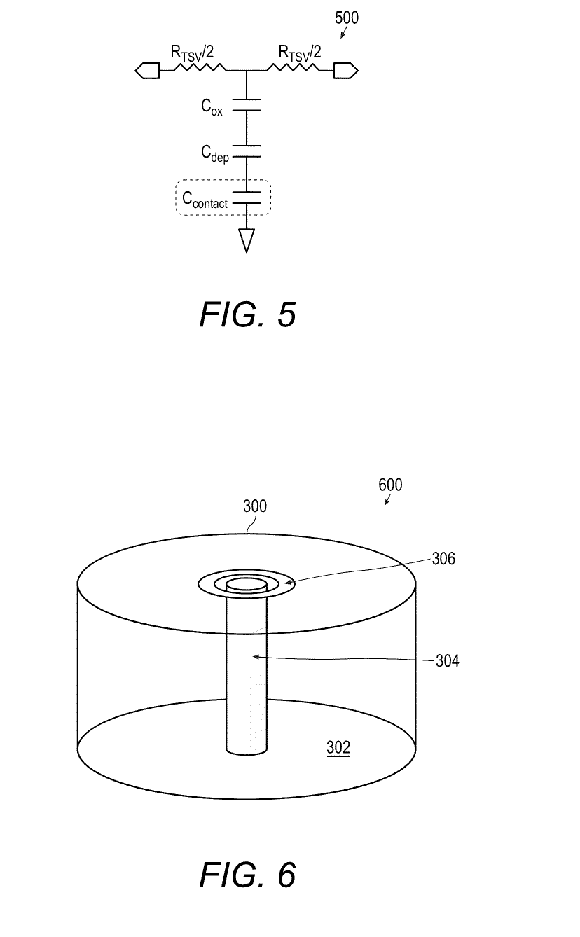

The semiconductor structure 300 as described in various embodiments above may reduce the overall capacitance of the via, as will be illustrated with regard to FIG. 5 below.

FIG. 5 shows an electrical model 500 of TSV in a semiconductor structure 300 of FIGS. 3-4, according to various embodiments.

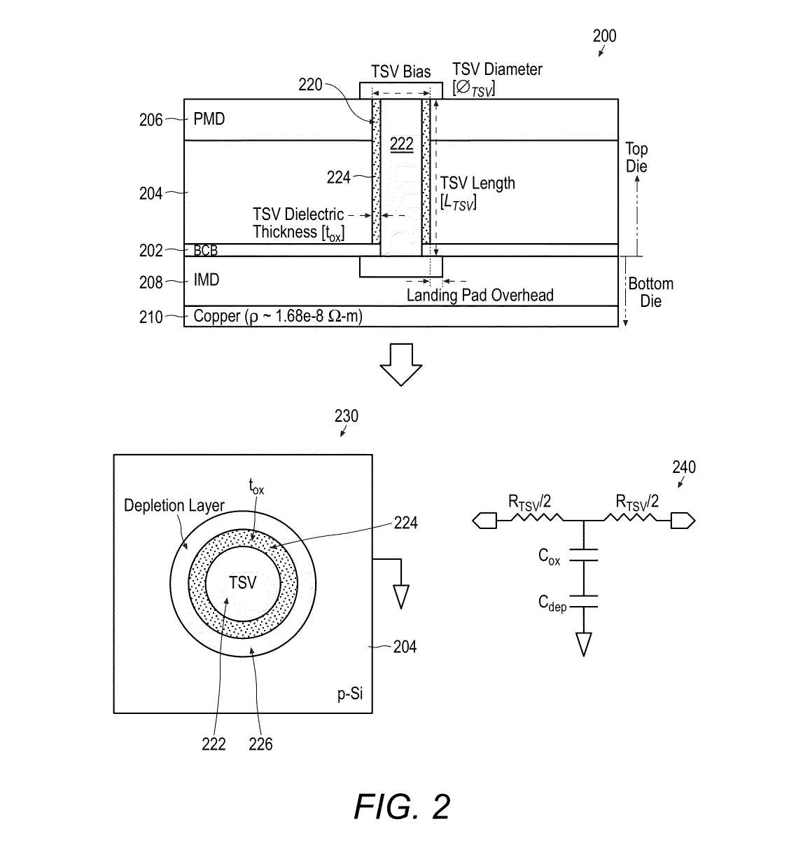

As shown in FIG. 5, the electrical model 500 includes the TSV resistance (R_{TSV}), and a series combination of the TSV oxide capacitance (Cₒₓ) and depletion capacitance (C_{dep}), similar to the lumped RC model 230 of FIG. 2.

Compared to the TSV structure of FIG. 2, the semiconductor structure 300 of various embodiments includes a capacitive structure 306, which introduces a further contact capacitance (C_{contact}) in series with the TSV oxide capacitance (Cₒₓ) and depletion capacitance (C_{dep}).

According to various embodiments, a smaller capacitive substrate contact capacitance (C_{contact}) is leveraged to achieve lower effective TSV capacitance such that 1/C_{TSV}=1/Cₒₓ+1/C_{dep}+1/C_{contact}. In this case, the contact capacitance C_{contact} provided by the capacitive structure 306 may be much lower compared to the oxide capacitance and the depletion capacitance, such that the effective capacitance may be close to the substrate contact capacitance C_{contact}.

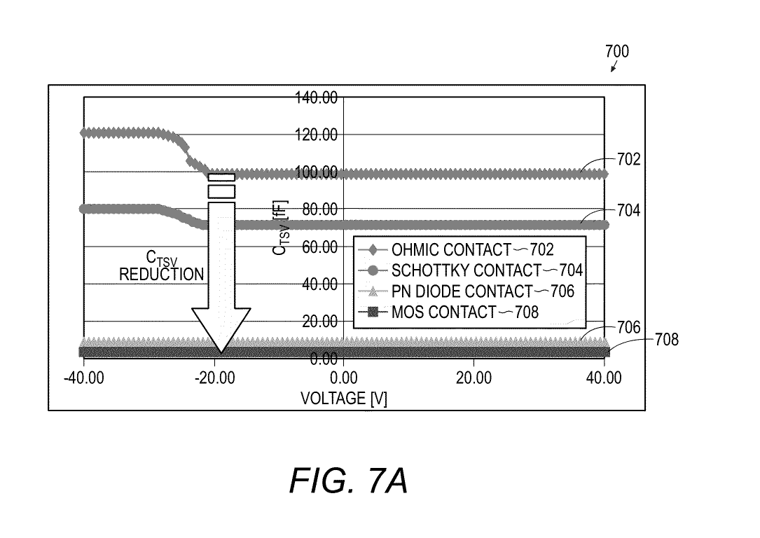

FIG. 6 shows a 3D view 600 of the semiconductor structure 300 according to various embodiments.

As shown in FIG. 6, the semiconductor structure 300 may include a semiconductor substrate 302; a via 304 extending through the semiconductor substrate 302; and a capacitive structure 306 surrounding at least a portion of the via 304. The capacitive structure 306 may include a metal layer 308 formed on the semiconductor substrate 302.

In the embodiments shown in FIG. 6, the metal layer 308 is formed as an annular layer surrounding the top surface of the via or TSV 304. The metal layer 308 together with the region of the semiconductor substrate 302 under the metal layer forms the capacitive structure 306 which surrounds at least a portion of the via 304. Various embodiments described with regard to FIGS. 3-5 above are analogously valid for the semiconductor structure shown in FIG. 6, and vice versa.

The semiconductor structure 300 as described in various embodiments above may be used or included in a 2.5D through silicon interposer, or in a 3D integrated circuit device.

Using the VLSI (very-large-scale integration) fabrication process, various embodiments of the capacitive substrate contacts 306 may be realized, including the Schottky substrate contact 410, the n⁺-p junction contact 420, and the MOS substrate contact 430 described in FIG. 4 above.

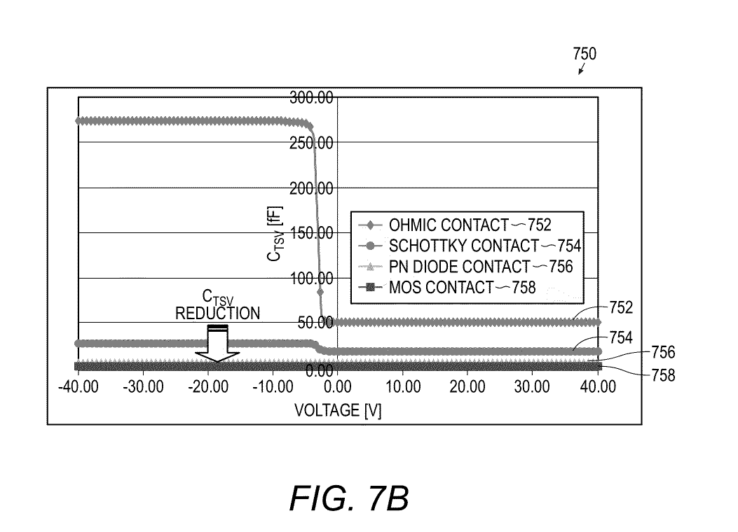

FIG. 7A shows simulated C-V characteristics 700 for various semiconductor structures including TSVs in 2.5D Through Silicon Interposer (TSI).

The SDevice (Sentaurus Device) simulation results for semiconductor structure of various embodiments as well as for existing TSV architecture with Ohmic p⁺ contact in 2.5D TSI are illustrated. FIG. 7A shows simulated C-V characteristic of a TSV with an Ohmic contact 702, simulated C-V characteristic of a TSV with a Schottky contact 704 (e.g. the Schottky contact 410 of FIG. 4), simulated C-V characteristic of a TSV with a PN diode contact 706 (e.g. the p-n junction contact 420 of FIG. 4), and simulated C-V characteristic of a TSV with a MOS contact 708 (e.g. the MOS contact 430 of FIG. 4).

In the simulation of FIG. 7A, the TSVs have a diameter of about 12 μm and a length of about 100 μm (i.e. φ_{TSV}=12 μm, L_{TSV}=100 μm), and an oxide layer thickness of about 1 μm (i.e. tₒₓ=1 μm). The TSVs are formed in a substrate having a doping concentration of 1.4×10¹⁵/cm³ (i.e. Na=1.4×10¹⁵/cm³).

FIG. 7B shows simulated C-V characteristics 750 for various semiconductor structures including TSVs in 3D integrated circuits.

The SDevice (Sentaurus Device) simulation results for semiconductor structure of various embodiments as well as for existing TSV architecture with Ohmic p⁺ contact in 3D ICs are illustrated. FIG. 7B shows simulated C-V characteristic of a TSV with an Ohmic contact 752, simulated C-V characteristic of a TSV with a Schottky contact 754 (e.g. the Schottky contact 410 of FIG. 4), simulated C-V characteristic of a TSV with a PN diode contact 756 (e.g. the p-n junction contact 420 of FIG. 4), and simulated C-V characteristic of a TSV with a MOS contact 758 (e.g. the MOS contact 430 of FIG. 4).

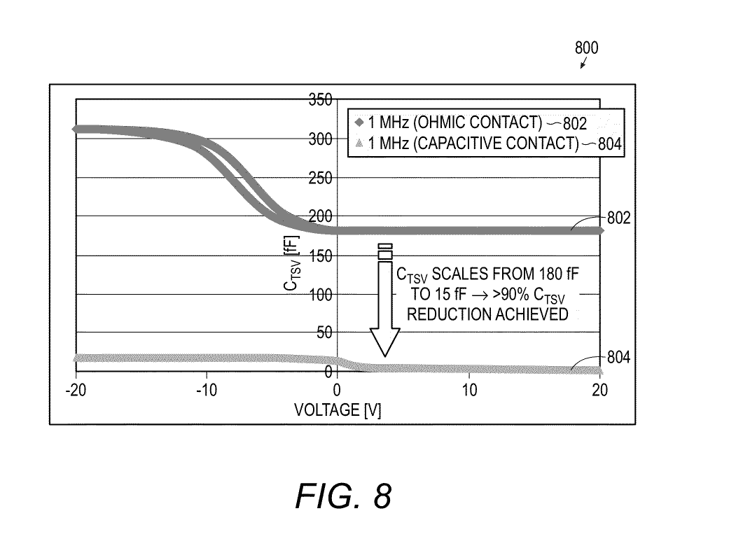

In the simulation of FIG. 8, the TSVs have a diameter of about 5 μm and a length of about 50 μm (i.e. φ_{TSV}=5 μm, L_{TSV}=50 μm), and an oxide layer thickness of about 100 nm (i.e. tₒₓ=100 nm). The TSVs are formed in a substrate having a doping concentration of 1.4×10¹⁴/cm³ (i.e. Na=1.4×10¹⁴/cm³).

In the simulation of both FIG. 7A and FIG. 7B, a circular substrate contact ring (i.e. Ohmic contact, Schottky contact, PN diode contact, or MOS contact) is surrounding the TSV, with a radius/thickness of about 1 μm at a distance of 1 μm from the edge of the TSV. Further, the Schottky contact 704, 754 may use a titanium-silicon Schottky interface. The PN diode contact 706, 756 may use a n⁺-p junction contact, wherein the n⁺ region has a donor doping concentration N_{d}=1×10²⁰/CM³. The MOS contact 708, 758 may have an oxide layer thickness of 500 nm.

As shown in FIG. 7A, the semiconductor structure with Schottky contact 704 achieves lower TSV capacitance compared to the TSV architecture with Ohmic contact 702. The semiconductor structure with PN diode contact 706 and with MOS contact 708 achieve significant TSV capacitance reduction compared to the TSV architecture with Ohmic contact 702.

As shown in FIG. 7B, the semiconductor structures with Schottky contact 754, PN diode contact 756 and with MOS contact 758 all achieve significant TSV capacitance reduction compared to the TSV architecture with Ohmic contact 752. The semiconductor structure with PN diode contact 756 and with MOS contact 758 achieve larger TSV capacitance reduction compared to the semiconductor structure with Schottky contact 754.

Table 1 shows the resulting TSV capacitance C_{TSV} for various capacitive substrate contacts of various embodiments as well as the percentage of TSV capacitance reduction (% C_{TSV}) achieved using the respective capacitive contacts.

TABLE 1
C_{TSV} and % C_{TSV} reduction using capacitive substrate
contacts in 2.5D TSI and 3D IC technologies

| | | % C_{TSV} | | % C_{TSV} |
|---|---|---|---|---|
| | TSV in | Reduc- | TSV in | Reduc- |
| | 2.5D TSI | tion | 3D ICs | tion |
| C_{TSV} with Ohmic p⁺ contact | 100 | — | 50 | — |
| C_{TSV} with Schottky contact | 71 | 29 | 18 | 64 |
| C_{TSV} with p-n junction | 10 | 90 | 5.1 | 89.8 |
| C_{TSV} with MOS contact | 4 | 96 | 2 | 96 |

It could be seen from Table 1 that the capacitive structure of various embodiments all provide TSV capacitance reduction over ohmic p+ substrate contacts, wherein the n⁺-p junction and MOS based capacitive substrate contacts achieve significant TSV capacitance reduction over ohmic p+substrate contacts. The Schottky contact based capacitive structure provides 29% C_{TSV} reduction over existing ohmic p+ substrate contacts in 2.5D TSI, and 64% C_{TSV} reduction over ohmic p+ substrate contacts in 3D ICs. The n⁺-p junction based capacitive substrate contacts provide about 90% C_{TSV} reduction over ohmic p+ substrate contacts for both 2.5D TSI and 3D ICs TSV technologies. The MOS based capacitive substrate contacts provide >90% (i.e. 96% in Table 1) C_{TSV} reduction over ohmic p+ substrate contacts for both 2.5D TSI and 3D ICs TSV technologies, which provides the largest TSV capacitance reduction.

FIG. 8 shows simulated C-V characteristics 800 for TSV of various embodiments in comparison to TSV with ohmic contact.

In the simulation of FIG. 8, the TSVs have a diameter of about 12 μm and a length/height of about 100 μm (i.e. P_{TSV}=12 μm, L_{TSV}=100 μm), and an oxide layer thickness of about 450 nm (i.e. tₒₓ=450 nm). In the simulation of FIG. 8, a circular Schottky contact ring is surrounding the TSV, with an inner annular diameter of about 16 μm and an outer annular diameter of about 20 μm.

As shown in FIG. 8, the TSV architecture with Ohmic contact 802 has a TSV capacitance C_{TSV} of about 180 fF at a frequency of 1 MHz, which is scaled to about 15 fF using the TSV architecture with Schottky contact 804. Accordingly, the semiconductor structure with Schottky contact 804 of various embodiments achieves more than 90% C_{TSV} reduction compared to the TSV architecture with Ohmic contact 802.

Fabrication and process integration of capacitive substrate contact of various embodiments above may utilize existing VLSI fabrication tools and methods. As a result, the fabrication and integration of capacitive substrate contact in the existing 2.5D TSI and 3D ICs manufacturing flows is feasible.

By way of example, n⁺-p junction contacts on a p-Si substrate may be readily implemented using n+ implantation available in the 3D ICs CMOS fabrication lines. By way of example, MOS substrate contacts can also be implemented using the same set of tools employed for TSV fabrication. For example, the MOS substrate contact can be created using the CVD (chemical vapor deposition) or thermal oxidation techniques followed by metal deposition and plating, making it suitable for integration in both the 2.5D TSI and 3D IC manufacturing lines. The implementation of Schottky contact is not necessarily a standard process in all the CMOS fabrication lines.

While implementing the capacitive substrate contacts of various embodiments it may be ensured as a stringent design rule that there are no ohmic substrate contacts in the vicinity. Ohmic substrate contact will provide low impedance path to ground nullifying the effect of high impedance capacitive substrate contact. For TSI, this may be readily achievable as there are no n⁺ and p⁺ contact on the TSI substrate. However, for 3D ICs, the nMOS and pMOS transistors may need to be fabricated using twin well technologies so that the p⁺ contacts do not provide low ground impedance for TSV signals. Adequate DRC (design rule checking) rules may be required to ensure lower C_{TSV} designs.

The capacitive substrate contacts of various embodiments are easy to implement without cost burden, for example, using modified standard FEOL (Front End of Line) contact module. The contact module may be modified with oxide CVD, and an additional barrier deposition may be performed before metal deposition. The implemented capacitive substrate contacts of various embodiments are easy to test as well. For example, capacitive bank of TSVs may be measured using a LCR meter.

Various embodiments provide TSV architectures using capacitive substrate contacts to reduce TSV capacitance C_{TSV}. Various capacitive substrate contact techniques, such as Schottky contact, n⁺-p junction contacts and MOS substrate contacts may be used. Reverse biased p-n junction contacts and MOS based capacitive substrate contacts may provide ˜90% C_{TSV} reduction compared to the ohmic p⁺ substrate contact counterparts, and may use the same tool sets employed in contemporary manufacturing lines for manufacture. The TSV structure with capacitive substrate contacts of various embodiments above may be used or comprised in a through silicon interposer as well as a three dimensional integrated circuit.

As described above, the dominant impact of parasitic capacitance (C_{TSV}) of TSV architectures on electrical performance of 3D circuits and systems cannot be ignored, and C_{TSV} of data signal TSVs is desired to be reduced as much as possible to build high speed data signaling in 2.5D TSI and 3D ICs.

On the other hand, TSVs carrying power/ground signals will be benefited by high decoupling capacitance, which may enable reliable power/ground networks. Hence, the TSV capacitance of the power/ground TSVs is desired to be as large as possible acting as a decoupling capacitor, conflicting with the requirements of low capacitance for data signal TSVs.

To satisfy the conflicting C_{TSV} requirements, power/ground TSVs with lower oxide thickness exhibiting large oxide capacitance are to be fabricated, while data signal TSVs with higher oxide thickness providing lower C_{TSV} are to be fabricated. The process development would involve the development of two disparate TSV modules such that one does not impact the other, which may not be desired in fabrication.

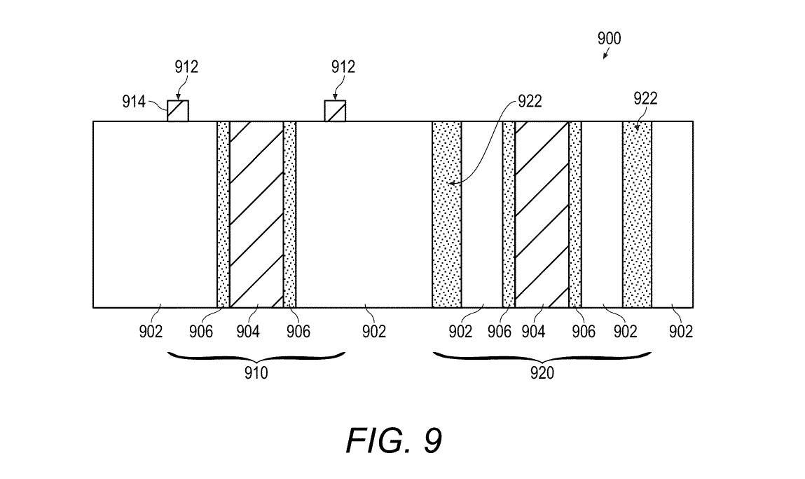

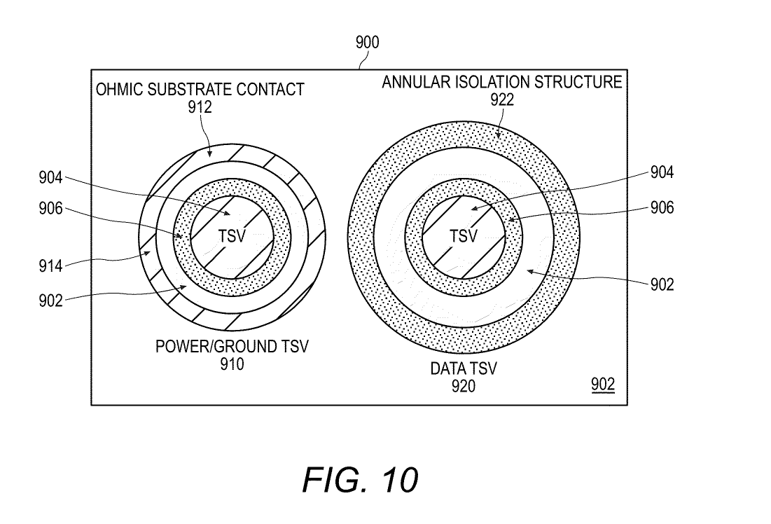

Various embodiments described below with regard to FIG. 9 and FIG. 10 provide a semiconductor structure, in which the existing TSV module with similar oxide liner thickness can be maintained but the conflicting C_{TSV} requirements for power/ground TSVs and data signal TSVs can be met.

FIG. 9 shows a semiconductor structure 900 according to various embodiments, in which a cross-section view of the semiconductor structure 900 having monolithically integrated power/ground TSV 910 and data signal TSV 920 is shown.

FIG. 10 shows a top view of the semiconductor structure 900 according to various embodiments, in which a power/ground TSV 910 and a data signal TSV 920 may be monolithically integrated in a semiconductor substrate 902.

Both of the power/ground TSV 910 and the data signal TSV 920 may include a conductive fill 904 through the semiconductor substrate 902, and an insulating layer 906 surrounding the conductive fill 904.

In various embodiments, the power/ground TSV 910 may further include an Ohmic substrate contact 912 formed at the surface of the semiconductor substrate 902. The Ohmic substrate contact 912 may include a metal layer 914 deposited on the surface of the semiconductor substrate 902 and a heavily doped region of the semiconductor substrate 902 located under the metal layer 914. The heavily doped region may be a p^{°}-doped region of a p-type substrate 902, or may be an n⁺-doped region of an n-type substrate 902.

In various embodiments, the data signal TSV 920 may further include an annular isolation structure 922 surrounding the data signal TSV 920, e.g. surrounding the insulating layer 906 of the data signal TSV 920 but having a distance away from the insulating layer 906. The annular isolation structure 922 may include an insulating material, e.g. an oxide or nitride material, e.g. SiO₂, or a low-k material.

The semiconductor substrate may be a silicon substrate. In various embodiments, the silicon substrate may be a p-type substrate or an n-type substrate.

For the power/ground TSV 910 without the annual isolation structure by with the Ohmic substrate contact (e.g. an Ohmic p⁺ substrate contact) in the vicinity, the TSV capacitance at low power frequencies may be equal to TSV oxide capacitance (Cₒₓ). Thus, the power/ground TSV 910 may provide a high capacitance.

For the data signal TSV 920 with the surrounding annular isolation regions 922, the TSV capacitance C_{TSV} may be exhibited as a series combination of oxide capacitance (Cₒₓ), depletion capacitance (C_{dep}) and an additional capacitance of the annular isolation structure 922 (Cₐₙₙᵤₗₐᵣ). Accordingly, the TSV capacitance C_{TSV} may be given by 1/C_{TSV}=1/Cₒₓ+1/C_{dep}+1/Cₐₙₙᵤₗₐᵣ. Thus, the TSV capacitance of the data signal TSV 920 is reduced due to the surrounding annular isolation capacitance provided by the annular isolation structure 922.

According to the semiconductor structure 900 of various embodiments, power/ground TSVs and data signal TSVs may be monolithically integrated, in which the TSV capacitance of data signal TSVs may be reduced by the annular isolation structure while the TSV capacitance of power/ground TSVs without the annular isolation structure may remain high. According to various embodiments, monolithic integration scheme employing the annular isolation structure to isolate data TSVs and power/ground TSVs is provided to satisfy the conflicting TSV capacitance requirements for data TSVs and power/ground TSVs.

In various embodiments, it may be desired as a design rule that there should not be any substrate contact in the region between the data signal TSV and its surrounding isolation region.

Fabrication and process integration to add an annular isolation ring to the existing TSV process module utilizes traditional VLSI fabrication tools and methods and is feasible. Annular isolation regions may be fabricated earlier or later than TSV fabrication module. The formation of annular isolation regions earlier than the TSV fabrication may aid in restricting the transfer of TSV fabrication stress to silicon. The process for the annular TSV structures may be simpler compared to the TSV fabrication as the annular region only needs to be filled using CVD oxide, instead of achieving conformal TSV isolation using CVD followed by metal filling in the annular region. Alternative dielectric polymers with reduced dielectric permittivity could also be employed for further data signal capacitance reduction. Moreover, in 3D ICs the annular isolation region may be as much as possible designed inside the transistor keep out zone, without leading any area loss for transistor placement.

According to the embodiments of FIG. 9 and FIG. 10, a semiconductor structure including TSVs is provided to monolithically integrate the high capacitance power/ground TSV and low capacitance data signal TSV. The annular isolation ring around the data signal TSV provides isolation between power/ground TSV and data signal TSV domains, such that power/ground TSVs with ohmic ground substrate exhibit high TSV oxide capacitance at low frequency while data signal TSV capacitance is reduced due to the annular isolation ring capacitance. The power/ground capacitance exhibited by the 3D IC TSV is comparable to MIMCAP (metal-insulator-metal capacitors) capacitance technologies and can be further increased by reducing the oxide liner thickness. Analysis of the impact of annular isolation centre radius and the annular isolation thickness demonstrates that thicker annular isolation ring closer to the data signal TSV will provide larger reduction in data signal TSV capacitance. The monolithic structure including TSVs with annular rings is feasible to manufacture.

In various embodiments different from FIG. 9 and FIG. 10, a semiconductor structure may include a power/ground TSV and a data signal TSV having different oxide liner thickness, so as to integrate a high capacitance power/ground TSV and a low capacitance data signal TSV. By way of example, the power/ground TSV may have a lower oxide liner thickness to achieve a higher capacitance, whereas the data signal TSV may have a higher oxide liner thickness to achieve a lower capacitance.

In various embodiments, the different oxide liner thickness provided for the power/ground TSV and the data signal TSV may be further combined with the semiconductor structure of FIG. 9 and FIG. 10.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A semiconductor structure, comprising:
a semiconductor substrate;
a via extending through the semiconductor substrate; and
a capacitive structure surrounding at least a portion of the via;
wherein the capacitive structure comprises a metal layer formed on the semiconductor substrate.

2. The semiconductor structure of claim 1, wherein the capacitive structure comprises a Schottky contact formed by the metal layer and a region of the semiconductor substrate under the metal layer.

3. The semiconductor structure of claim 2, wherein the semiconductor substrate has a doping of a predetermined concentration and of a predetermined dopant type, and the region of the semiconductor substrate comprised in the Schottky contact has a doping of the predetermined concentration and of the predetermined dopant type.

4. The semiconductor structure of claim 3, wherein the semiconductor substrate having the doping of the predetermined concentration forms an extrinsic semiconductor substrate.

5. The semiconductor structure of claim 1,
wherein the capacitive structure comprises the metal layer and a p-n junction formed in the semiconductor substrate;
wherein the p-n junction comprises a first region of the semiconductor substrate having the doping of a first concentration and of a first dopant type, and a second region of the semiconductor substrate have a doping of a second concentration and of a second dopant type, the second dopant type being opposite to the first dopant type; and
wherein the second region of the semiconductor substrate is arranged inbetween the metal layer and the first region of the semiconductor substrate.

6. The semiconductor structure of claim 5, wherein the second concentration is higher than the first concentration.

7. The semiconductor structure of claim 5, wherein the second concentration is at least one hundred times higher than the first concentration.

8. The semiconductor structure of claim 5, wherein the first region is a p-doped region, and the second region is a n⁺-doped region.

9. The semiconductor substrate of claim 1,
wherein the capacitive structure comprises a metal-oxide-semiconductor contact; and
wherein the capacitive structure comprises the metal layer, a region of the semiconductor substrate under the metal layer, and an oxide layer arranged in between the metal layer and the region of the semiconductor substrate.

10. The semiconductor structure of claim 9, wherein the oxide layer is deposited on the surface of the semiconductor substrate.

11. The semiconductor structure of claim 9, wherein the oxide layer is formed in a further region of the semiconductor substrate in between the metal layer and the region of the semiconductor substrate.

12. The semiconductor structure of claim 9, wherein the semiconductor substrate and the region of the semiconductor substrate under the metal layer have a doping of a predetermined concentration and of a predetermined dopant type.

13. The semiconductor structure of claim 1, wherein the via is formed within an opening through the semiconductor substrate.

14. The semiconductor structure of claim 13, wherein the via comprises:
an insulating layer formed at a wall of the opening; and
a conductive fill formed within the opening with the insulating layer surrounding the conductive fill.

15. The semiconductor structure of claim 14, wherein the metal layer is formed at a distance away from the insulating layer.

16. The semiconductor structure of claim 1, wherein the metal layer is formed as one of an annular layer, a rectangular layer, or a square layer surrounding the via on the surface of the semiconductor substrate, and is formed at a distance away from the via.

17. A through silicon interposer comprising the semiconductor structure of claim 1.

18. A three dimensional integrated circuit device comprising the semiconductor structure of claim 1.
